(19) United States
(12) Patent Application Publication
(10) Pub. No.: US 2006/0087307 A1
(43) Pub. Date: Apr. 27, 2006

(54) Single pin multilevel integrated circuit test interface

(76) Inventor: Rudi De Winter, Heusden-Zolder (BE)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 10/519,346

(22) PCT Filed: Jun. 19, 2003
(86) PCT No.: PCT/IB03/02380

§ 371 Date: Aug. 22, 2005

(30) Foreign Application Priority Data
Jun. 21, 2002 (GB) 0214516.7

(51) Int. Cl. G01R 13/02

(52) U.S. Cl. 324/76.47

(57) ABSTRACT

An integrated circuit comprises one or more integrated circuit elements which may interact with other circuitry via one or more input/output pins. In the present invention the circuit elements include and interface element for interfacing with external test circuitry. The interface element communicates with the external test circuitry via a single input/output pin dedicated for testing.

The present invention relates to an interface arrangement allowing the complete testing of a digital integrated circuit via a single pin.

A known method of testing digital circuits, especially digital integrated circuits or the digital sections of mixed analogue and digital circuits, involves the use of scan path testing methods. Such methods involve configuring the internal storage elements of a digital system such that they can operate in two or more modes. In one mode they perform the designed task for the normal operation of the digital system. In at least one other mode they are connected in groups in long serial shift register chains. The first storage element in each chain has its serial input connected to an input pin of the integrated circuit and the last element of each chain has its serial output connected to an output pin. The clocking signals of the storage elements are also arranged to be connected to a common clock line for each chain, which is also connected to an input pin. By configuring internal storage elements in test mode and serially clocking data into the chains of storage elements the internal storage elements can be set to any combination of logic states. The internal storage elements are then switched back to normal mode and the integrated circuit operated for a predetermined time. The internal storage elements are then switched back to test mode. The logic states of the internal storage elements are then serially shifted out for subsequent evaluation by the tester.

To avoid the need for large numbers of additional pins on an integrated circuit to accommodate these test features additional logic is often arranged by switching pins between normal and test mode functions. This switching may be conveniently arranged to be under the same or similar control as the switching of the storage elements between normal and test mode.

This need to supply additional test pins or to share pins between functions can lead to additional size and logic complexity and can thereby induce testing errors in the integrated circuit.

Accordingly there is a need for a means of achieving the benefits of scan path testing but with minimal additional circuitry and with minimal risk to the normal functioning of the device.

According to the present invention there is provided an integrated circuit comprising one or more integrated circuit elements and one or more input/output pins, the one or more integrated circuit elements including an interface element for interfacing with external test circuitry, the interface element communicating with the external test circuitry via a single input/output pin dedicated for testing wherein the single pin connected operates with several logic thresholds.

Preferably the interface element is embedded into a digital integrated circuit as a single pin interface between the digital integrated circuit and an external test circuitry. The interface element receives test data and commands from the test circuitry, in response to which the scanpath block controls and commands the scan path elements within the digital integrated circuit and returns the resulting data to the test engine.

Preferably the different logic thresholds define several logic levels, which enable the data and timing signals to be differentiated on a single pin.

Preferably positive action is required from the external test circuitry to maintain the digital integrated circuit in a test mode. This is to ensure that when the connection to the test engine fails, or is not present the digital integrated circuit operates in its normal manner.

The invention will now be described further by way of example only and with reference to the accompanying drawing in which:—

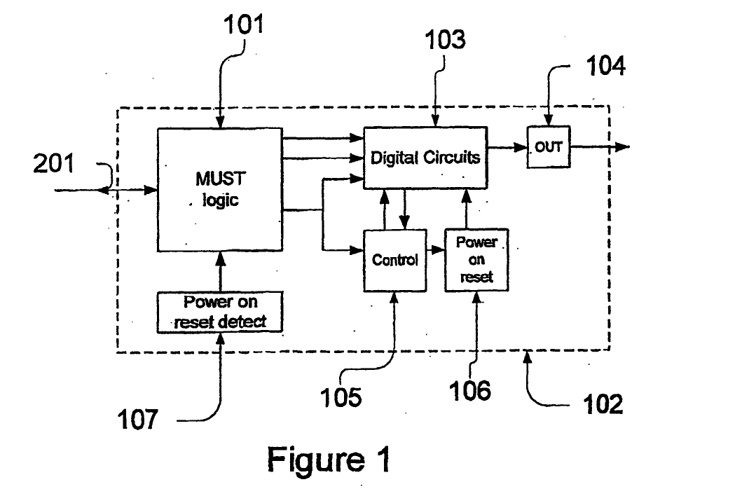

FIG. 1 is a schematic view showing the interface element residing within an integrated circuit according to the present invention;

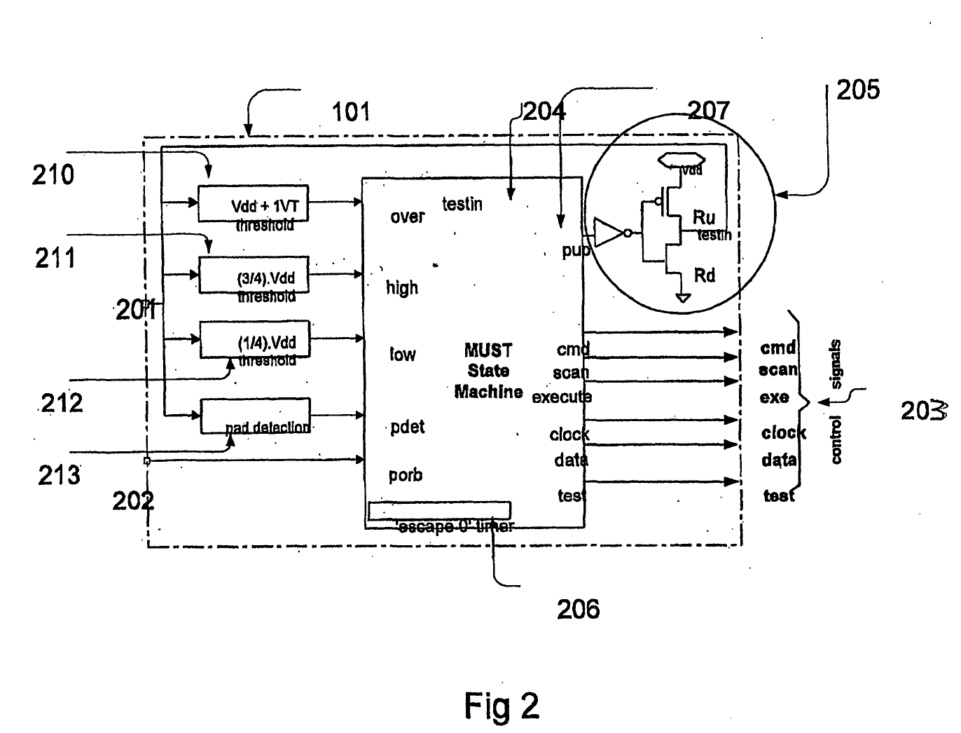

FIG. 2 is a schematic diagram showing the connections to the interface element from the rest of the integrated circuit;

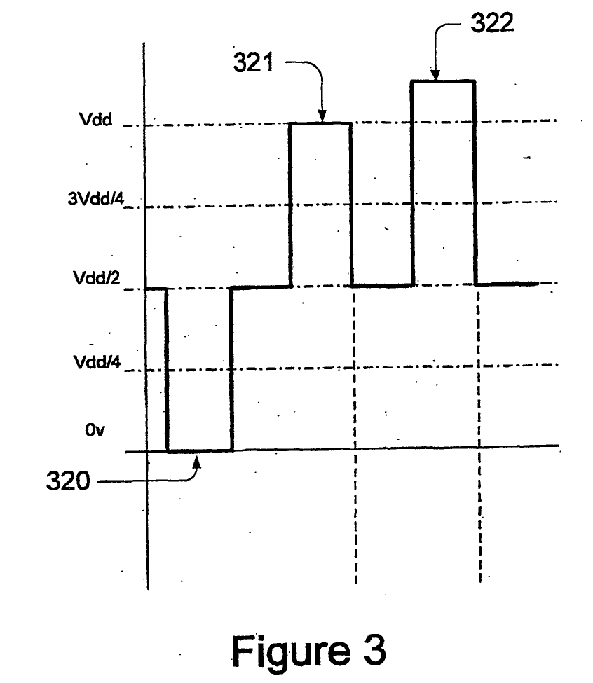

FIG. 3 shows typical voltage levels on the pin linking the interface element with external test circuitry;

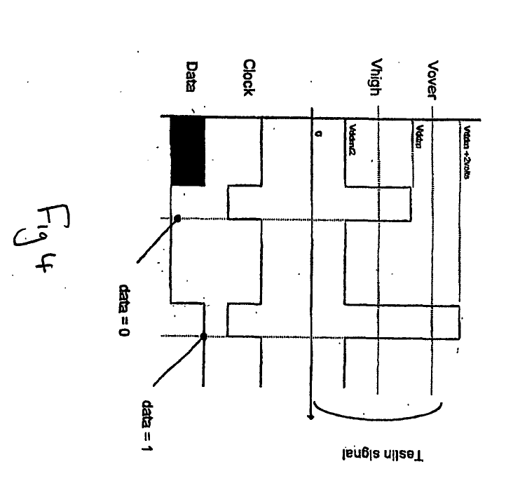

FIG. 4 shows clock and data signals extracted from typical waveforms;

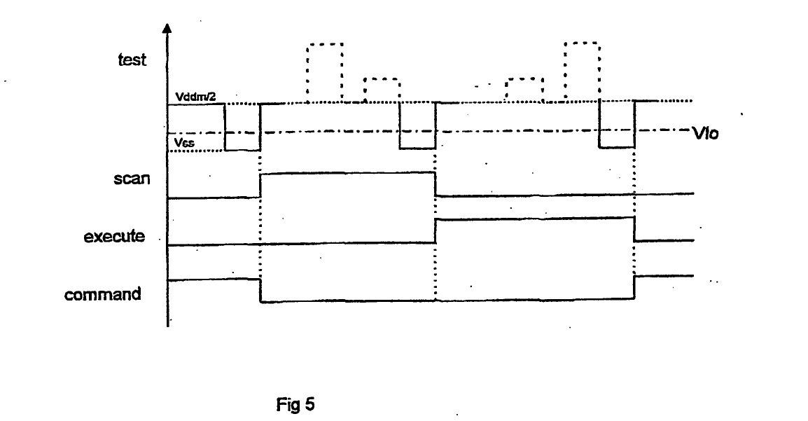

FIG. 5 shows typical signals during synchronisation;

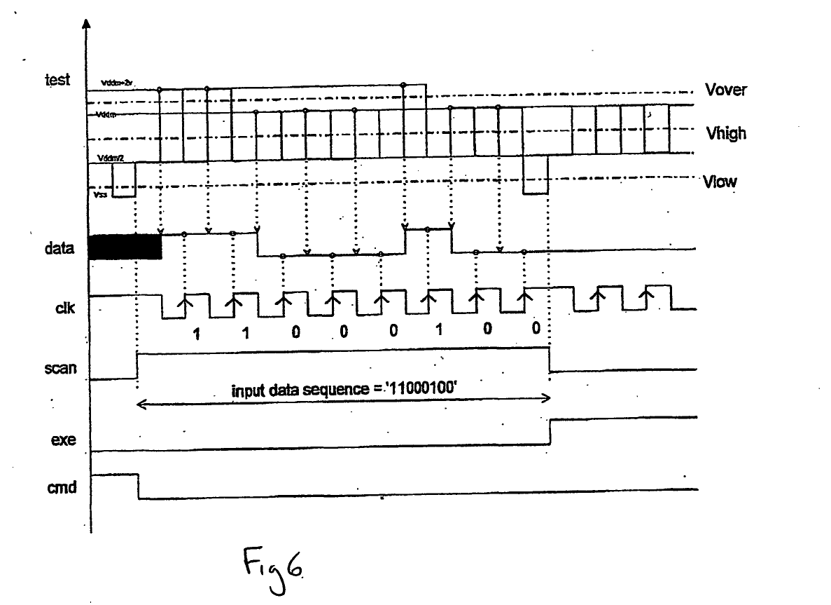

FIG. 6 shows typical signals during scan mode;

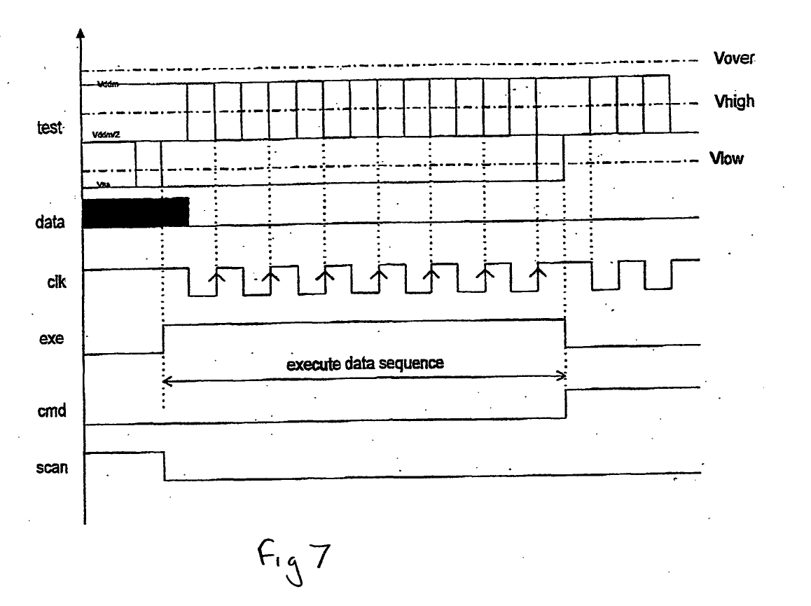

FIG. 7 shows typical signals during execute mode;

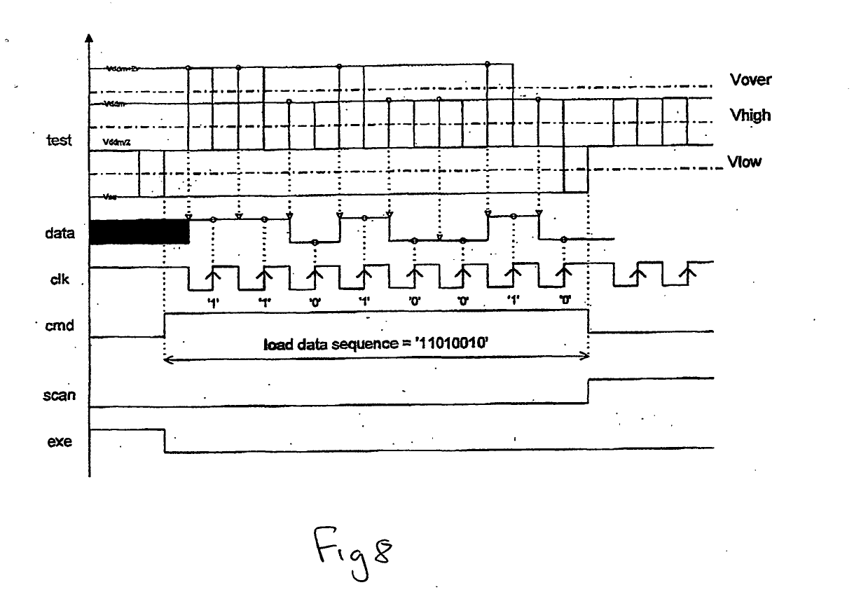

FIG. 8 shows typical signals during command mode; and

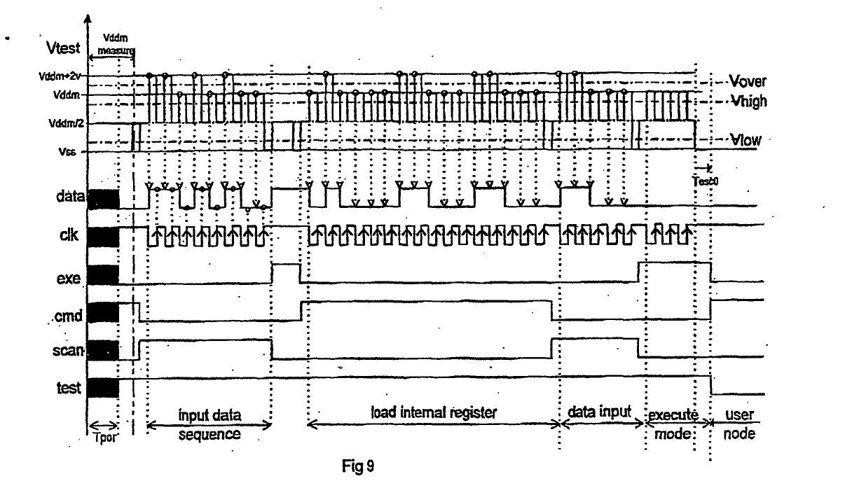

FIG. 9 shows a complete sequence for illustrative purposes.

Referring to FIG. 1, an interface element 101 according to the present invention is embedded in an integrated circuit (IC) 102. This is the application where the benefits of the invention are best exploited since requiring fewer pins on an IC can lead to significant cost savings both in the manufacture of the IC itself and the manufacture of the circuit board on which the IC is mounted.

The IC shown in FIG. 1 additionally comprises: digital circuits 103; control circuits 105 to handle switching into and out of the scan test mode; power on reset circuit 106 to set the internal logic to a known state after the removal and reconnection of the power supply; a typical output pin 104; and a power on reset detect circuit 107 to determine when the Power on Reset circuit has operated and to maintain synchronism between the external tester and the digital circuits.

FIG. 2 shows the interface element 101 in more detail. The multi-level input pin 201 is connected to various threshold circuits 210, 211, 212. The signals from these enable a state machine 204 within the interface element to determine the voltage on the pin 201 to within one of four voltage bands. These voltage bands are defined relative to the thresholds: more than one volt above Vdd is denominated ‘over’; more then ¾ of Vdd is denominated ‘high’; and more than ¼ of Vdd is denominated ‘low’.

The remaining detector ‘pad detection’ 213 determines whether there is a connection an external tester or other external circuitry world by assessing the voltage on the pin 201. If the voltage on the pin 201 is held at a voltage below ‘low’ for a period of time determined by an ‘escape 0 timer’ 206 then the circuit block 101 will decide there is no tester connected to pin 201. It will then revert to normal mode, thereby allowing digital circuits 103 operate in their as-designed mode.

The output signals 203 produced by the interface element are those necessary for the correct operation for the scan path testing of the IC. In a preferred embodiment general these are shown as command (cmd), scan, execute (exe), clock, data and test. These signals are a sufficient set to operate the scan path testing of most digital logic circuits.

FIG. 3 shows some input voltage levels on the pin 201. Typical voltages applied to the pin 201 by the external tester are 0v, Vdd/2, Vdd and Vdd+2. The tolerance on any of these levels is determined by the value of Vdd itself and the accuracy of the threshold circuits.

To enable the interface element to operate, the tester needs to know an accurate value for Vdd. Vdd may be determined by the IC 102 itself and therefore not be a known voltage. To assist the tester to determine the value of Vdd a pull up, pull down resistor means is also included in the design. This is shown in FIG. 2 as circuit elements 205. Under normal conditions the state of signal pup 207 is such as to cause a pull down resistor to be connected to pin 201. If the tester is not connected to pin 201 then the action of the escape 0 timer 206 will cause the state machine 204 and hence the whole IC 102 to be in normal mode. When interface element 101 is under control of the external tester via pin 201 the signal pup 207 can be switched such that a pull up resistor is connected to pin 201. In this condition the tester can measure the value of Vdd directly from pin 201.

The interpretation of the voltage levels and the transitions between voltage levels of input signals to pin 201 in a preferred embodiment is defined as follows.

If an input signal dwells below Vdd/4 for a period greater than the timeout period of escape 0 timer 206, it is defined as a reset signal and the test is aborted.

If the input voltage on pin 201 at the end of the power on reset period of the IC 102 is greater than 3Vdd/4 it is taken to indicate the presence of an external tester. In such a case, the Pull up resistor is connected to pin 201 and the tester can then revert to high impedance measurement status to determine the value of Vdd. The state machine is now in command mode.

A pulse going below Vdd/4 for a short period 320, illustrated in FIG. 3, is a mode advance pulse, active on its positive transition through Vdd/4. This mode advance pulse steps the state machine cyclically around the three defined modes, command, scan and execute. This is illustrated in FIG. 5. The three modes are used to determine the destination of the data and/or clocks that are transmitted whilst in that mode.

The first mode advance pulse 320 after the Power on reset period of IC 102 causes the pull down resistors to be connected to pin 201 instead of the pull up resistor and clocks the state machine from command mode to scan mode.

A clock pulse 321, 322 applied to pin 201 is defined as a positive then a negative transition through 3Vdd/4.

The voltage level to which pin 201 rises determines the data level. If the voltage does not rise above Vdd+1, 321, then the data is taken to be a ‘0’. If the voltage rises to above Vdd+1, 322, then the data is taken to be a ‘1’.

The positive transition on pin 201 at the start of a clock pulse defines the time at which the data is set, this is subsequently scanned when the negative transition on pin 201 takes place at the end of a clock pulse. This process is illustrated in FIG. 4

The use of these signals is further illustrated in FIGS. 6, 7, 8 and 9.

FIG. 6 shows a data input sequence commencing from the point at which the low pulse on pin 201 steps the system into scan mode and shows a sequence of voltage transitions for loading a data stream ‘11000100’ into the interface element before the system is stepped into execute mode.

FIG. 7 shows a sequence of signals where in execute mode there is no required data and the only activity is the generation of clock signals.

FIG. 8 shows a sequence that loads a data sequence ‘11010010’ into the command register in a manner similar to the loading of data into the scan path shown in FIG. 6.

FIG. 9 shows a typical combination of sequences showing the switching between modes and the general arrangement of the voltage level sequences on pin 201. FIG. 9 starts with the measurement of Vdd and then progressing to loading a dat sequence in scan mode as shown in FIG. 6. The system then switches to scan mode before loading data in execute mode as shown in FIG. 8. The test data is then input in a similar manner before switching to execute mode. The sequence finishes by returning to user mode following the termination of the test by the holding of pin 201 low for sufficient time for the ‘escape 0 timer’ 206 to operate.

It is of course to be understood that the invention is not intended to be restricted to the details of the above described embodiment which is described by way of example only.

1. An integrated circuit comprises one or more integrated circuit elements and one or more input/output pins, the one or more integrated circuit elements including an interface element for interfacing with external test circuitry, the interface element communicating with the external test circuitry via a single input/output pin dedicated for testing wherein the single pin connected operates with several logic thresholds and wherein the absence of positive action from the external test circuitry the integrated circuit defaults from test mode to normal mode.

2. An integrated circuit according to claim 1 wherein the interface element is embedded into the integrated circuit as a single pin interface between the digital integrated circuit and the external test circuitry.

3. An integrated circuit according to claim 2 wherein the interface element receives test data and commands from the external test circuitry in response to which a crash block controls and commands scan path elements within the digital integrated circuit and returns the resulting data to the external test circuitry.

4. An integrated circuit according to claim 1 wherein the logic thresholds define several logic levels which enable data and timing signals to be differentiated on a single pin.

5. An integrated circuit according to claim 1 wherein a “pad detection” detector determines whether there is a connection an external tester or other external circuitry by assessing the voltage on the single pin.

6. An integrated circuit according to claim 1 wherein if a voltage on the single pin is held at a voltage below “low” for a period of time determined by an “escape 0 timer” then the integrated circuit will decide there is no tester connected to the single pin.
